(19) United States
(12) Patent Application Publication
(10) Pub. No.: US 2014/0138667 A1
(43) Pub. Date: May 22, 2014

(54) ORGANIC SEMICONDUCTOR DEVICE, AND METHOD FOR PRODUCING SAME

(71) Applicant: Tokai Rubber Industries, Ltd., Aichi-ken (JP)

(72) Inventors: Shingo HIBINO, Aichi-ken (JP); Ayako HIMURO, Aichi-ken (JP); Yuzo TAKAO, Aichi-ken (JP)

(73) Assignee: TOKAI RUBBER INDUSTRIES, LTD., Aichi-ken (JP)

(21) Appl. No.: 14/164,737

(22) Filed: Jan. 27, 2014

Related U.S. Application Data
(63) Continuation of application No. PCT/JP2012/071607, filed on Aug. 27, 2012.

(30) Foreign Application Priority Data
Aug. 30, 2011 (JP) 2011-187769

(51) Int. Cl. H01L 51/44; H01L 51/52

(52) U.S. Cl. CPC H01L 51/448; H01L 51/5253
USPC 257/40; 438/99

(57) ABSTRACT

An organic semiconductor device includes a laminate and films sealing the laminate in which excellent connection precision is achieved between connection lands and electrodes by suppression of slipping between the laminate and the films upon sealing of the laminate under evacuation, and the laminate is highly sealed. The organic semiconductor device has, between a laminate and a first film substrate, an antislip members that suppress slipping between the laminate and the first film substrate upon sealing of the laminate. An open hole and an electrode contained in the laminate are kept aligned by suppressing of the slipping. The electrode contained in the laminate is connected outside the device through the open hole by a conductive material.

### TECHNICAL FIELD

The present invention relates to an organic semiconductor device and a method for producing the same, and more specifically relates to an organic semiconductor device suitably used as an organic electroluminescence device (i.e., an organic light-emitting device or an organic EL device) or an organic thin-film solar cell, and a method for producing the same.

### BACKGROUND ART

Conventionally, an organic semiconductor device is known, which is a semiconductor device containing an organic material. Examples of the organic semiconductor device include an organic light-emitting device containing an organic light-emitting material and an organic thin-film solar cell containing organic materials in combination such as an electro-conductive polymer and a fullerene.

The organic light-emitting device has a basic structure comprising, on a surface of a transparent glass substrate, a transparent anode layer, a light-emitting organic material layer, and a cathode layer, in the order presented. The organic light-emitting device emits light by recombination of an electron injected from the cathode layer and a hole injected from the anode layer in the organic light-emitting material layer.

An example of the structure of the conventional organic light-emitting device is shown in FIG. 6. As shown in the figure, the organic light-emitting device comprises an anode 102 having a shape of a plurality of transparent parallel lines on a transparent glass substrate 101. On the anode 102, a light-emitting functional layer 103 is formed. On the functional layer 103, a cathode 104 that has a shape of a plurality of parallel lines and crosses over the anode 102. The cathode 104 is made of a metal, and is prepared, for example, by vacuum deposition.

One of the end portions of the anode 102 or cathode 104 is connected to an anode or cathode driving IC 106 via an anode or cathode extraction electrode, respectively. The anode or cathode driving IC 106 is connected to an external signal electrode that is provided in a predetermined position on the glass substrate 101. Thus, the organic light-emitting device is provided with input terminals for driving signals. The light-emitting functional layer 103 is sensitive to moisture. In order to maintain the properties of the light-emitting functional layer 103, a sealing can 108 made of a metal is mounted on and joined to the glass substrate 101 via an adhesive 109 in order to seal the anode 102, functional layer 103 and cathode 104 inside and to shield them against the moisture in the atmosphere.

However, in the above-described structure, there is a possibility that the moisture outside enters into the sealed space from gaps around a connecting line that connects the electrode outside the device. If the light-emitting functional layer 103 is exposed to the moisture in the atmosphere, the functional layer 103 may suffer degradation, and thus the light-emitting property of the functional layer 103 may be deteriorated.

To solve the problem, PTL 1 discloses an organic light-emitting device. The device comprises a laminate comprising an anode, an organic light-emitting material layer, and a cathode on a glass substrate; and a ceramic substrate comprising conductive patterns on both sides connected to each other through throughholes. In the device, the substrates are joined to each other, and the laminate is sealed and enclosed hermetically. The conductive pattern on one of the sides of the ceramic substrate is connected to the anode and cathode. Thus, the anode and cathode contained in the laminate are connected to an external driving circuit through the throughholes.

### CITATION LIST

### Patent Literature

PTL1: JP 3290584 B

### SUMMARY OF INVENTION

### Technical Problem

In the device described above, the anode and cathode contained in the laminate sealed are connected to the external driving circuit through the throughholes formed in the ceramic substrate that seals the laminate. Since connection lands of the conductive pattern formed on one of the sides of the ceramic substrate are connected to the anode and cathode upon the sealing of the laminate, high positioning precision is required between the connection lands of the conductive pattern and the anode and cathode. The connection lands are so small in area that a positional displacement between the two substrates greatly affects the positioning precision between the connection lands and the electrodes to be connected to each other. Since this problem relates to the positional displacement between the substrates, an organic thin-film solar cell may have a similar problem as well as the organic light-emitting device.

Though the device described above has the problem of the positioning precision, the present inventors modified the device by applying films as the substrates in order to increase convenience of the device in handling, and thus obtained a tape-shaped organic semiconductor device such as a tape-shaped organic light-emitting device. Moreover, in order to decrease the amount of the moisture contained in the gas enclosed between the film substrates, and consequently to further suppress degradation of the organic material layer sealed with the film substrates by the moisture, they evacuated a space enclosed by the film substrate, and subsequently joined the substrates to each other when the evacuation is completed.

Further, the present inventors found that the modified configuration and the modified product ion method described above may cause slipping between the film substrates and the laminate containing the organic material layer upon the sealing of the laminate. In the modified production method, the connection lands of the conductive pattern and the anode and cathode are connected to each other upon sealing of the laminate. Thus, the slipping between the film substrates and the laminate may cause a positional displacement between the connection lands and the anode and cathode to be connected to each other because the connection lads are very small in area.

In order to suppress the positional displacement, the film substrates may be joined to each other under evacuation with positioned relative to each other by a positioning device such as a positioning pin. However, since the film substrates are not rigid bodies, use of the positioning device may cause an undulation or distortion in the film substrates when a slipping force is applied to the film. The undulation or distortion may lead to warping of the film substrates after the sealing.

An object of the present invention is to provide an organic semiconductor device comprising a laminate and films sealing the laminate in which excellent connect ion precision is achieved between connection lands and electrodes by suppression of slipping between the laminate and the films upon sealing of the laminate under evacuation, and the laminate is highly sealed. Another object of the present invention is to provide a method producing the same.

### Solution to Problem

To achieve the objects and in accordance with the purpose of the present invention, an organic semiconductor device according to a preferred embodiment of the present invention contains a first film substrate comprising a film and an insulating sealing membrane formed on a surface of the film, a second film substrate comprising a transparent film and an insulating sealing membrane formed on a surface of the transparent film, and a laminate comprising a transparent substrate, an organic semiconductor layer comprising an organic semiconductor material, an anode layer, and a cathode layer, the laminate enclosed and sealed with the first and second film substrates, wherein the first film substrate comprises an open hole extending through the thickness of the first film substrate, the device comprises, between the laminate and at least one of the first and second film substrates, an antislip member that suppresses slipping between the laminate and the at least one of the first and second film substrates that occurs upon sealing of the laminate between the films, the open hole and an electrode contained in the laminate are kept aligned by the suppression of the slipping, and the electrode contained in the laminate is connected outside the device through the open hole by a conductive material.

In the device, the antislip member is preferably formed between the laminate and the first film substrate around a periphery of the open hole. It is preferable that the conductive material is a cured or sintered product of a conductive paste deposited in the open hole in the first film substrate, and the open hole is closed with the cured or sintered product. It is preferable that the cured or sintered product of the conductive paste is electrically connected to the electrode contained in the laminate via an anisotropic conductive paste or film, and a part of the anisotropic conductive paste or film is in the open hole closed with the cured or sintered product. The conductive paste is preferably a paste-form composition that comprises a conductive filler comprising a metallic nanofiller. It is preferable that the first and second film substrates are joined to each other at peripheral portions of the film substrates with a sealant, and the laminate is enclosed and sealed hermetically with the first and second substrates. It is preferable that the first film substrate comprises conductive patterns on surfaces of the film and the insulating sealing membrane, and the conductive patterns are electrically connected to each other through the open hole by the conductive material.

In another aspect of the present invention, a method according to a preferred embodiment of the present invention is for producing an organic semiconductor device comprising a first film substrate comprising a film and an insulating sealing membrane formed on a surface of the film, a second film substrate comprising a transparent film and an insulating sealing membrane formed on a surface of the transparent film, and a laminate comprising a transparent substrate, an organic semiconductor layer comprising an organic semiconductor material, an anode layer, and a cathode layer, the laminate enclosed and sealed with the first and second film substrates. The method comprises forming an open hole extending through the thickness of the first film substrate through which an electrode contained in the laminate is to be connected outside the device, filling the open hole with a conductive material, enclosing the laminate between the first and second film substrates, placing, between the laminate and at least one of the first and second film substrates, an antislip member that suppresses slipping between the laminate and the at least one of the first and second film substrates that occurs upon sealing the laminate, and sealing the laminate and connecting the electrode contained in the laminate outside the device through the open hole via the conductive material, by joining the first and second film substrates to each other under evacuation with keeping the open hole and the electrode contained in the laminate aligned.

In the method, it is preferable that before the open hole is formed in the first film substrate, the antislip member is formed on the surface of the insulating sealing membrane of the first film substrate in a position in which the open hole is to be formed, having a larger area than the open hole to be formed. The open hole in the first film substrate is preferably filled with the conductive material by depositing of a conductive paste in the open hole and subsequent curing or sintering of the conductive paste. It is preferable that a cured or sintered product of the conductive paste and the electrode contained in the laminate are electrically connected to each other via an anisotropic conductive paste or film, and a part of the anisotropic conductive paste or film is flowed into the open hole closed with the cured or sintered product.

### Advantageous Effects of Invention

The organic semiconductor device according to the preferred embodiment of the present invention contains the film substrates as sealing members to seal the laminate. The device further contains, between the laminate and the first or second film substrate, an antislip member that suppresses slipping between them upon the sealing of the laminate under evacuation. Since the slipping between the laminate and the first or second film substrates is thus suppressed, the conductive material, which is deposited in the open hole and works as a connection land, is aligned with and connected to the anode or cathode contained in the laminate without a positional displacement. Thus, the device has excellent connection precision between the connection land formed in the sealing member and the anode or cathode contained in the laminate.

Further, the anode or cathode contained in the laminate is connected to an external driving circuit through the open hole formed in the first film substrate, but not through a gap between the two substrates joined to each other as in the conventional device. Thus, the laminate containing the organic semiconductor layer is highly sealed with the sealing members containing the first film substrates.

When the antislip member is formed between the laminate and the first film substrate around a periphery of the open hole, the antislip member suppresses generation of cracks in the insulating sealing membrane upon formation of the open hole in the first film substrate. Thus, deterioration of the sealing property of the film substrate by the cracks is suppressed.

When the conductive material is a cured or sintered product of a conductive paste deposited in the open hole in the first film substrate, and the open hole is closed with the cured or sintered product, the open hole is closed with the conductive material highly hermetically. Thus, the electrode contained in the laminate is connected outside the device through the open hole via the conductive material while keeping the laminate highly sealed.

When the cured or sintered product of the conductive paste is electrically connected to the electrode contained in the laminate via an anisotropic conductive paste or film, and a part of the anisotropic conductive paste or film is in the open hole closed with the cured or sintered product, voids formed in the open hole upon curing or sintering of the conductive paste are filled with the anisotropic conductive paste or film. Thus, the sealing of the laminate is ensured.

When the conductive paste is a paste-form composition that comprises a conductive filler comprising a metallic nanofiller, a dense sintered product is formed upon sintering of the product. Thus, a high conductivity and a high sealing effect are both achieved.

In the method for producing the organic semiconductor device according to the preferred embodiment of the present invention, the first and second film substrates are joined to each other under evacuation, with placing, between the laminate and the first or second film substrates, the antislip member that suppresses slipping between the laminate and the film substrate upon the sealing of the laminate. Since the slipping is suppressed by the antislip member, the conductive material deposited in the open hole, which works as a connection land in the sealing member, is aligned with and connected to the anode or cathode contained in the laminate without a positional displacement. Thus, the device produced by the method has excellent connection precision between the connection land formed in the sealing member and the anode or cathode contained in the laminate.

Further, the anode or cathode contained in the laminate is connected to an external driving circuit through the open hole formed in the first film substrate as the sealing member that seals the laminate containing the organic semiconductor layer, but not through a gap between the two substrates joined to each other as in the conventional device. Thus, in the device produced by the method, the laminate is highly sealed. Furthermore, since the laminate is sealed under evacuation, the moisture content in the space in which the laminate is enclosed is decreased. Thus, degradation of the organic semiconductor layer is suppressed. For example, a light-emitting property of an organic light-emitting device is highly maintained.

When, before the open hole is formed in the first film substrate, the antislip member is formed on the surface of the insulating sealing membrane of the first film substrate in a position in which the open hole is to be formed, having a larger area than the open hole to be formed, generation of cracks in the insulating sealing membrane upon formation of the open hole in the first film substrate is suppressed. Thus, deterioration of the sealing property of the film substrate by the cracks is suppressed.

When the open hole in the first film substrate is filled with the conductive material by depositing of a conductive paste in the open hole and subsequent curing or sintering of the conductive paste, the open hole is closed with the conductive paste highly hermetically. Thus, the electrode contained in the laminate is connected outside the device by the conductive material through the open hole while keeping the laminate highly sealed.

When a cured or sintered product of the conductive paste and the electrode contained in the laminate are electrically connected to each other via an anisotropic conductive paste or film, and a part of the anisotropic conductive paste or film is flowed into the open hole closed with the cured or sintered product, voids formed in the open hole upon curing or sintering of the conductive paste are filled with the anisotropic conductive paste or film. Thus, the sealing of the laminate is ensured.

### BRIEF DESCRIPTION OF DRAWINGS

FIG. 1 is an external perspective view showing an organic semiconductor device according to a preferred embodiment of the present invention.

FIG. 2 is a cross-sectional view along the line A-A in FIG. 1 showing an internal structure of the same.

FIGS. 3A-3G are process drawings showing a part of a method for producing the same.

FIG. 4 is a process drawing showing a method producing an organic semiconductor device according to a preferred embodiment of the present invention.

FIGS. 5A-5C show variations of arrangement of antislip members.

FIG. 6 shows a sealing structure in a conventional organic light-emitting device.

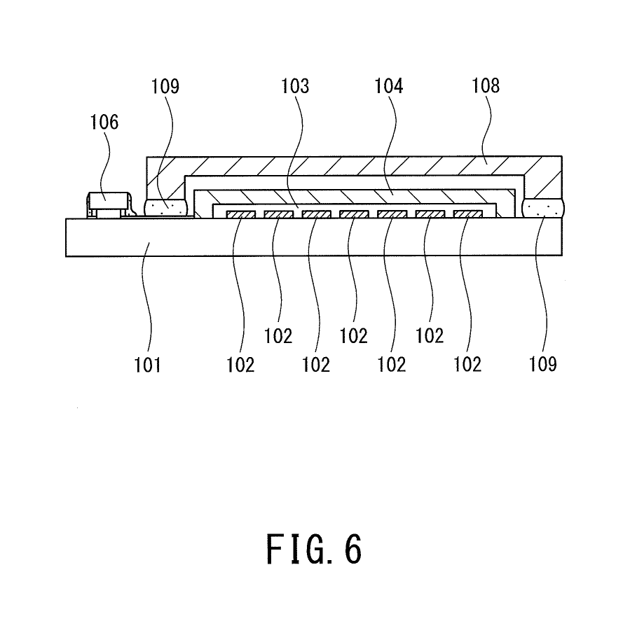

### DESCRIPTION OF EMBODIMENTS

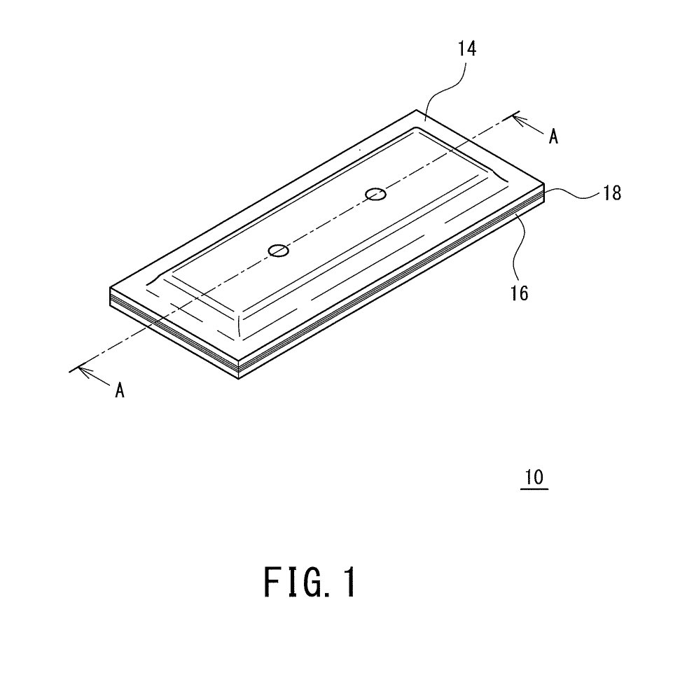

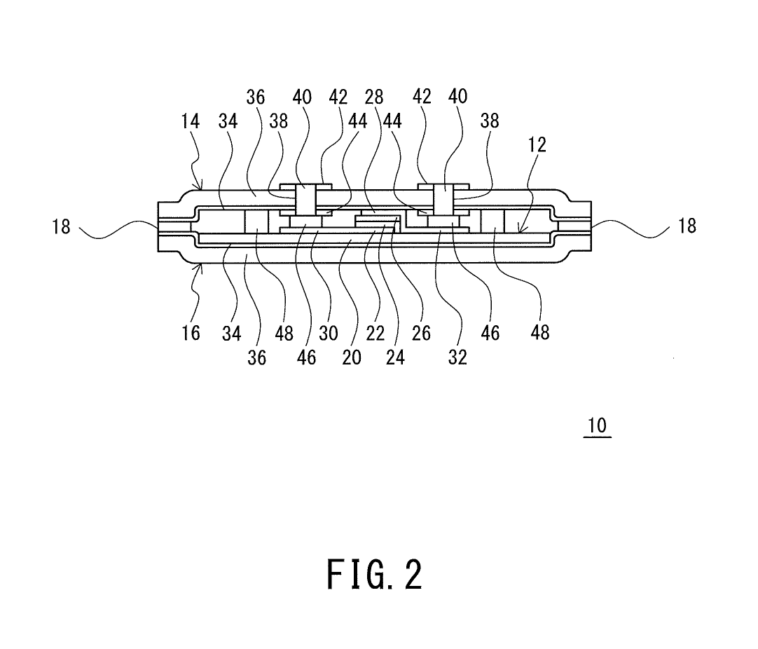

A detailed description of an organic semiconductor device according to a preferred embodiment of the present invention will now be provided. FIG. 1 is an external perspective view showing an organic semiconductor device according to a preferred embodiment of the present invention. FIG. 2 is a cross-sectional view along the line A-A in FIG. 1 showing an internal structure of the device.

As shown in FIGS. 1 and 2, in an organic semiconductor device 10 according to a preferred embodiment of the present invention, a laminate 12 that contains an organic semiconductor layer containing an organic semiconductor material is sealed with sealing members 14, 16.

As shown in FIG. 2, the laminate 12 has, for example, a transparent anode layer 22, a hole transport layer 24, the organic semiconductor layer 26, and a cathode layer 28. The layers 22, 24, 26, 28 are laminated in the order presented on a transparent substrate 20 that is made of a transparent material and has a film or plate shape. The organic semiconductor layer 26 provides the organic semiconductor device 10 with a function, and is made of a material according to the function. The organic semiconductor device 10 may preferably be used as an organic light-emitting device or an organic thin-film solar cell.

In the case of an organic light-emitting device, the organic semiconductor layer 26 is made of an organic material that contains an organic light-emitting material. Thus, the laminate 12 of the light-emitting device has a light-emitting function. The laminate 12 emits light by recombination of an electron injected from the cathode layer 28 and a hole injected from the transparent anode layer 22 in the organic semiconductor layer 26. In the case of an organic thin-film transistor, the organic semiconductor layer (i.e., a photoelectric conversion layer) 26 contains an electron-donating organic material (i.e., a p-type organic semiconductor material) and/or an electron-accepting organic material (i.e., an n-type organic semiconductor material). Examples of the organic thin-film solar cell include a Schottky type and a heterojunction type.

The sealing members 14, 16 consist of film substrates. Specifically, the sealing member consists of a first film substrate 14 and a second film substrate 16. The first and second film substrates 14, 16 are placed on opposite sides of the laminate 12: the first film substrate 14 covers the anode layer 28 while the second film substrate 16 covers the transparent substrate 20. The sealing members 14, 16 are joined to each other at peripheral portions thereof via a sealant 18, with enclosing the laminate 12 in between. Thus, the sealing members 14, 16 seal the laminate 12 at the peripheral portions thereof. It is preferable that the sealing members 14, 16 are joined to each other on three or four sides thereof, or they are joined to each other to have an envelope-like shape.

Each of the first film substrate 14 and the second film substrate 16 contains a film 36 and an insulating sealing membrane 34 formed on one of the surfaces of the film 36. Each of the film substrates 14, 16 is placed with the surface of the insulating sealing membrane 34 facing inside and the surface of the film 36 facing outside. The insulating sealing membrane 34 enhances the effect of suppressing entrance of a gas or moisture into the sealed space.

On the surface of the insulating sealing membrane 34 of the first film substrate 14, a conductive pattern (not shown) to be connected to a cathode of the cathode layer 28 is formed, for example, of a copper foil. On the surface of the film 36, a conductive pattern (not shown) is formed, for example, of a copper foil to be connected to a device (not shown) outside the organic semiconductor device 10 such as an anode driving IC, a cathode driving IC, and other electronic devices.

The first film substrate 14 has open holes 38 extending through the thickness of the film substrate 14. The open holes 38 are closed with conductive material 40. The conductive material 40 is electrically connected to external terminals 42 on a side on which the film 36 is placed, and is connected to internal terminals 44 on a side on which the insulating sealing membrane 34 is placed. The external terminals 42 are electrically connected to the conductive pattern formed on the surface of the film 36 while the internal terminals 44 are electrically connected to the conductive pattern formed on the surface of the insulating sealing membrane 34. Thus, the conductive pattern formed on the surface of the insulating sealing membrane 34 and the conductive pattern formed on the surface of the film 36 are electrically connected to each other by the conductive material 40 through the open holes 38.

An anode terminal 30 and a cathode terminal 32 are formed extending from the transparent anode layer 22 and the cathode layer 28 in the laminate 12, respectively. The terminals 30, 32 are connected to the conductive material 40 deposited in the open holes 38 via conductive adhesive layers 46. The conductive material 40 works as connection lands of the conductive pattern. Thus, the electrodes in the laminate 12 are connected outside the device 10 by the conductive material 40 through the open holes 38.

Between the laminate 12 and the first film substrate 14, antislip members 48 that suppress slipping between the laminate 12 and the film substrate 14 that occurs upon the sealing of the laminate 12. The laminate 12 and the film substrate 14 are restrained from slipping with respect to each other by the antislip members 48. Thus, the conductive material 40 in the open holes 38, which works as connection lands of the conductive pattern, and the anode and cathode in the laminate 12 are aligned with and electrically connected to each other.

The film substrate 20 in the laminate 12 may be made of a glass or a resin material. The substrate 20 is preferably made of the resin material because of excellent flexibility of the resin material. Preferable examples of the resin material making up the transparent substrate 20 include a polyethylene terephthalate, a polyethylene naphthalate, a polycarbonate, a polyimide, a polyethersulfone, a polyetherimide, a polyphenylene sulfide, a polysulfone, a polyetheretherketone, a polyamide, a polymethyl methacrylate, a polyacrylate, and a cycloolefin polymer. They may be used singly or in combination. The thickness of the transparent substrate 20 may be in a range of 3 to 1000 μm, 10 to 500 μm, or 10 to 300 μm.

The transparent anode layer 22 in the laminate 12 is preferably made of a material having a high transparency in order to transmit the emitted light. Examples of the material include a metal, a conductive compound, and a mixture thereof that have high work functions (of 4 eV or higher). More specific examples of the material include tin-doped indium oxide (ITO) and indium zinc oxide (IZO). They may be used singly or in combination.

The transparent anode layer 22 may be formed by any of vacuum deposition, sputtering, spin coating, casting, LB, pyrosol, and spraying methods. The thickness of the transparent anode layer 22 formed by the method may be in a range of 10 to 5000 nm or 50 to 300 nm. The resistance of the transparent anode layer 22 may be in a range of 7 to 1000 Ω/sq. or 10 to 200 Ω/sq.

The hole transport layer 24 in the laminate 12 may contain an organic material such as phthalocyanine, a polyaniline, an oligothiophene, a benzyne derivative, triphenylamine, a pyrazoline derivative, and a triphenylene derivative. Among them, polyethylenedioxythiophene doped with polystyrenesulfonate (PEDOT:PSS) is preferable, which is soluble in water. The materials listed above may be used singly or in combination. The hole transport layer 24 may also contain an electron acceptor such as a halogenated metal, a Lewis acid, and an organic acid in order to increase the hole mobility in the layer 24.

The hole transport layer 24 may be formed from a solution of the organic material in a solvent. Specifically, a film of the solution is formed, for example, by a spin coating method. Then the film formed is heated and dried. An alcoholic solvent such as isopropyl alcohol may be used as solvent to prepare the solution, as well as water. The thickness of the hole transport layer 24 thus formed may be within a range of 1 to 200 nm or 10 to 100 nm.

In the case of the organic light-emitting device, the organic semiconductor layer 16 in the laminate 12 contains an organic light-emitting material. The organic semiconductor layer 26 may consists of the organic light-emitting material, or may contain, in addition to the organic light-emitting material, an organic material (i.e., a host material) that has a carrier transport property (i.e., a hole, electron, or bipolar transport property). The color of the light emitted from the organic semiconductor layer 26 may be controlled by the type and amount of the organic light-emitting material contained. The organic semiconductor layer 26 may be formed in the same way that the hole transport layer 24 is formed. The thickness of the organic semiconductor layer 26 thus formed is preferably 200 nm or smaller in order to provide practical brightness of the emitted light.

The organic light-emitting material contained in the organic semiconductor layer 26 preferably has an excellent film-forming property and a high film stability when formed into a film. The material is not limited specifically, and examples of the material include a metal complex such as tris-(8-hydroxyquinolinato)aluminum (Alq3), a polyphenylenevinylene (PVV) derivative, and a polyfluorene derivative. The layer 26 may further contain a small amount of another organic light-emitting material such as a fluorescent dye to control the color of the emitted light.

If the organic semiconductor layer 26 contains the host material in addition to the organic light-emitting material and if the host material provides a sufficiently good film-forming property and sufficiently high film stability when formed into a film, the organic semiconductor layer 26 may contain, in addition to the organic light-emitting material, a fluorescent dye that hardly forms a stable film alone. Examples of the dye include coumarine, a DCM derivative, quinacridone, perylene and rubrene. The host material is not limited specifically, and examples of the host material include Alq3, triphenyldiamine (TPD), an electron-transporting oxadiazole derivative (PBD), a polycarbonate copolymer, and a polyvinylcarbazole.

In the case of the Schottky-type organic thin-film solar cell, the organic semiconductor layer (photoelectric conversion layer) 26 may contain either any electron-emitting material or any electron-donating material. Specific examples of the materials include a single crystal of an organic compound such as pentacene; a conductive polymer and a derivative thereof such as a poly-3-methylthiophene, a polyacetylene, a polyphenylene, a derivative thereof, a polyphenylenevinylene, a derivative thereof, a polysilane, a derivative thereof, a polyalkylthiophene, and a derivative thereof; a synthetic dye such as a porphyrin derivative, a phthalocyanine derivative, a merocyanine derivative, and a chlorophyll; and an organic metal polymer.

In the case of the heterojunction-type organic thin-film solar cell, examples of the electron-accepting organic material contained in the organic semiconductor layer 26 include a CN-poly(phenylene-vinylene), MEH-CN-PPV, a polymer containing a —CN or —CF₃ group, polyfluorene derivative, a derivative of a fullerene such as C₆₀, a carbon nanotube, a perylene derivative, a polycyclic quinone, and quinacridone. Examples of the electron-donating organic material contained in the organic semiconductor layer 26 include a polyphenylene, a derivative thereof, a polyphenylenevinylene, a derivative thereof, a polysilane, a derivative thereof, a polyalkylthiophene, a derivative thereof, a porphyrin derivative, a phthalocyanine derivative, and an organic metal polymer.

Preferable examples of the material contained in the cathode layer 28 in the laminate 12 include metal, an alloy composition, a conductive compound, and a mixture thereof that have low work functions (of 4 eV or lower). Examples of the metal include Al, Ti, In, Na, K, Ca, Mg, Ba, Li, Cs, Rb, and a rare earth metal while examples the alloy composition include Na—K, Mg—Ag, Mg—Cu, Al—Ca, and Al—Li alloys.

The cathode layer 28 may be formed in the same way that the transparent anode layer 22 is formed. The thickness of the cathode layer 28 thus formed may be within a range of 0.1 to 1000 nm, or 1 to 300 nm. The layer 28 may have a resistance of 1 to 150 Ω/sq. or 10 to 40 Ω/sq.

An electron transport layer may be formed between the organic semiconductor layer 26 and the cathode layer 28 in order to improve the electron transport property. Preferable examples of a material contained in the electron transport layer include an electron-transporting material such as a nitro-substituted fluorene derivative, a diphenylquinone derivative, a thiopyrandioxide derivative, an tetracarboxylic anhydride of a heterocyclic compound such as naphthalene and perylene, carbodiimide, a fluorenylidenemethane derivative, anthraquinodimethane, an anthrone derivative, an oxadiazole derivative, a quinoline derivative, a quinoxaline derivative, a perylene derivative, a pyridine derivative, a pyrimidine derivative, and a stilbene derivative. Preferable examples of the material also include an aluminum-quinolinol complex such as tris-(8-hydroxyquinoline)aluminum (Alq3). The electron transport layer may be formed in the same way that the hole transport layer 24 is formed. The thickness of the electron transport layer thus formed may be within a range of 0.1 to 120 nm or 0.5 to 50 nm.

The anode terminal 30 and the cathode terminal 32 in the laminate 12 may be made of conductive materials. Examples of the conductive materials include metal materials such as copper, aluminum, silver, gold, and an alloy thereof. The terminals 30, 32 may be formed in the same way that the transparent anode layer 22 is formed. The terminals 30, 32 thus formed may have thicknesses in a range of 50 nm to 1 mm, or 100 nm to 300 μm.

As the films 36 of the first film substrate 14 and the second film substrate 16, organic polymer films made of an organic polymer, or metal foils may be used preferably. The organic polymer films are more preferably used because the films have high optical transparencies and because cracks are hardly formed in the films when the films are bent.

The organic polymer films may preferably be made of a polyester such as a polyethylene terephthalate and a polyethylene naphthalate; a polyolefin such as a biaxially oriented polypropylene; a polyethersulfone; and a transparent polyimide. Among them, the polyethylene terephthalate or polyethylene naphthalate may be used more preferably, from the viewpoint of surface flatness, heat resistance, and a production cost. The films 36 may have thicknesses in a range of 3 to 1000 μm, 10 to 500 μm, or 10 to 300 μm.

The insulating sealing membranes 34 of the first film substrate 14 and the second film substrate 16 may preferably be made of an insulating material such as SiO₂. TiO₂, SiON, SiN, and AlN. Making up dense layers, these materials provide excellent gas barrier membranes that have high sealing properties and highly block a gas and moisture from entering into the sealed space. Since the insulating sealing membrane 34 of the second film substrate 16 is placed facing the transparent anode layer 22 in the laminate 12, it is preferable that the membrane 34 of the second film substrate 16 is transparent to transmit the emitted light. Meanwhile, the insulating sealing membrane 34 of the first film substrate 14 may be transparent or opaque since the membrane 34 is placed facing the cathode layer 28 in the laminate 12 and is not required to transmit the emitted light. The insulating sealing membranes 34 may be formed by a physical gas-phase method such as vapor deposition and sputtering methods. The membranes 34 thus formed may have thicknesses within a range of 5 to 1000 nm or 1 to 300 nm.

The open holes 38 in the first film substrate 14 may have inner diameters within a range of 0.1 to 10 mm or 0.2 to 2 mm. The conductive material 40 deposited in the open holes 38 may preferably be made from a conductive paste. The conductive material 40 is prepared by curing or sintering of the conductive paste, for example, by heating. The conductive paste 40 improves the sealing property of the film substrate 14 at the open holes 38 by closing the open holes 38. The conductive paste contains metal microparticles, a dispersion medium, and a dispersing agent that disperses the metal microparticles in the dispersion medium. The metal microparticles contain metal cores and an organic component that covers the metal cores.

It is preferable that the metal microparticles are made of an organometallic salt or an organometallic complex. Examples of the organometallic salt or complex include an aliphatic metal salt, a metal salt of alkylsulfonic acid, a metal alkoxide, and an acetylacetonato complex. Preferable examples of the metal contained in the organometallic salt or complex includes silver, gold, a platinum-group metal (such as Pt, Pd, Ir, Rh, Ru, and Os), Cu, Ni, Zr, Nb, Mo, Ca, Sr, Ba, In, Co, Zn, Cd, Al, Ga, Fe, Cr, Mn, and Y.

The metal microparticles preferably have diameters in a range of 2 nm to 100 μm, and more preferably in a range of 5 to 100 nm. Further, it is preferable that the metal microparticles are so-called metallic nanofiller particles. Metallic nanofiller particles become dense upon sintered, and thus provide both a high conducting property and a high sealing property.

Examples of the dispersion medium include an alcohol such as terpineol, dihydroterpineol, decanol, hexanol, methanol, ethanol, ethyl carbitol, butyl carbitol, a diol, a glycol, and a polyol; an amine such as dimethylformamide (DMF) and N-methyl-2-pyrrolidone (NMP); a hydrocarbon such as hexane, toluene, xylene, octane, decane, undecane, and tetradecane; a ketone such as methyl ethyl ketone (MEK) and acetone; an ether such as tetrahydrofurane (THF) and dipropylene glycol monomethyl ether; and an ester such as ethyl acetate, ethyl carbitol acetate, and butyl carbitol acetate.

Examples of the dispersing agent include amide-amine salts of a polyester acid and a polyetherester acid.

The external and the internal terminals 42, 44 that are connected to the conductive material 40 and the conductive patterns on the first film substrate 14 may be made of conductive materials, as the anode terminal 30 and the cathode terminal 32 in the laminate 12. Examples of the conductive materials include copper, aluminum, silver, gold, and an alloy thereof. The external and internal terminals 42, 44 and the conductive patterns on the first film substrate 14 may be formed in the same way that the transparent anode layer 22 is formed. The external and internal terminals 42, 44 thus formed may have thicknesses of 10 nm to 100 μm or 100 nm to 10 μm.

The conductive adhesive layers 46 that connect the conductive material 40 and the anode and cathode terminals 30, 32 in the laminate 12 to each other may preferably be made of a conductive material. Examples of the conductive material making up the layers 46 include an anisotropic conductive paste and an anisotropic conductive film because the anisotropic paste or film makes proper connections between conductors arranged with a narrow pitch.

The anisotropic conductive paste (or film) is made of a large number of particles of conductive filler and a polymeric material that surrounds the particles and keeps the particles separated from each other. The anisotropic conductive paste is defined as an anisotropic conductive material in which the polymeric material has a liquid property at room temperature while the anisotropic conductive film is defined as an anisotropic conductive material in which the polymeric material has a solid property at room temperature and a liquid property when heated.

The anisotropic conductive paste (or film) is conductive in a thickness direction in which the particles of the conductive filler are arranged with each particle electrically connected to one or more other particles while being insulated in an in-plane direction in which the particles are separated from each other.

Consequently, the anisotropic conductive paste (or film) are placed in a form of a layer or a membrane so that the thickness direction is along a connecting direction in which the conductive material 40 and the anode terminal 30 or the cathode terminal 32 in the laminate 12 are electrically connected to each other while the in-plane direction is along the plane of the laminate 12.

Examples of the conductive filler contained in the anisotropic conductive paste (or film) include metal particles, carbon particles, and resin particles coated with conductive coating layers. The particles of the conductive filler may not have granular shapes. Examples of the filler that does not have a granular particle shape include a carbon nanotube. The diameters of the granular conductive filler particles are preferably within a range of 1 to 500 μm, and more preferably within a range of 5 to 100 μm.

The metal particles and the conductive coating layers may be made of gold, silver, a platinum-group metal (such as platinum, palladium, ruthenium, rhodium, osmium, and iridium), nickel, copper, zinc, iron, lead, tin, aluminum, cobalt, indium, chromium, titanium, antimony, bismuth, germanium, cadmium, a tin-lead alloy, a tin-copper alloy, a tin-silver alloy, or a tin-lead-silver alloy.

Resin particles to be coated with the conductive coating layers may be made of a polyethylene, a polypropylene, a polystyrene, a polyvinyl chloride, a polyvinylidene chloride, a polytetrafluoroethylene, a polyisobutylene, a polybutadiene, a polyalkylene terephthalate, a polysulfone, a polycarbonate, a polyamide, a phenol-formaldehyde resin, a melamine-formaldehyde resin, a benzoguanamine-formaldehyde resin, a urea-formaldehyde resin, a (meth)acrylic ester polymer, or a divinylbenzene polymer such as a divinylbenzene polymer, a divinylbenzene-styrene copolymer, and a divinylbenzene-(meth)acrylic acid ester copolymer.

Examples of the polymeric material that surrounds the conductive filler include various thermosetting resins, thermoplastic resins, and rubbers. Examples of the thermosetting resins include epoxy, melamine, phenolic, diallylphthalate, bismaleimide-triazine, unsaturated polyester, polyurethane, phenoxy, polyamide, and polyimide resins. Examples of the thermoplastic resins include polyamide, polyester, polycarbonate, polyphenylene oxide, polyurethane, polyacetal, polyvinyl acetal, polyethylene, polypropylene, and polyvinyl resins. Examples of the rubbers and elastomers include rubbers and elastomers that have one or more functional groups such as hydroxyl, carboxyl, vinyl, amino, and epoxy groups.

The thicknesses of the conductive adhesive layers 46 containing the polymeric material are preferably within a range of 2 to 1000 μm, and more preferably in a range of 10 to 200 μm.

The antislip members 48 may be made of a material that has a high friction coefficient. Examples of the material include an adhesive agent and a polymer material. It is preferable that the amount of volatile ingredients in the material is small from the viewpoint of suppression of outgassing from the material. For example, preparing the material without using a low-boiling solvent suppresses the outgassing. When the antislip members 48 are made of the polymer material, it is preferable that the antislip members 48 have roughness on contacting surfaces (for example, on surfaces in contact with the sealing members 14, 16 and the laminate 12) thereof. Examples of the polymer material that provides the surface roughness include a polyolefin such as a polyethylene and an elastomer.

The antislip members 48 may be formed by a screen printing method. The thicknesses of the antislip members 48 is preferably 10 μm or larger, and more preferably 20 μm or larger to suppress the slipping sufficiently. On the other hand, the upper limit of the thickness is preferably 500 μm, and more preferable 200 μm because the conductive material 40 and the conductive adhesive layers 46 are stably joined to each other inside the thickness. The antislip members 48 may be formed on the surface of the insulating sealing membrane 34 of the first film substrate 14 or the second film substrate 16 or on the surface of the transparent substrate 20 in the laminate 12.

The sealant 18 that joins the peripheral portions of the first and second film substrates 14, 16 to each other is preferably made of an adhesive agent. The sealant 18 preferably has low gas permeability. Examples of the sealant material having the low gas permeability include an epoxy adhesive agent. The material may contain an additional ingredient such as an inorganic filler.

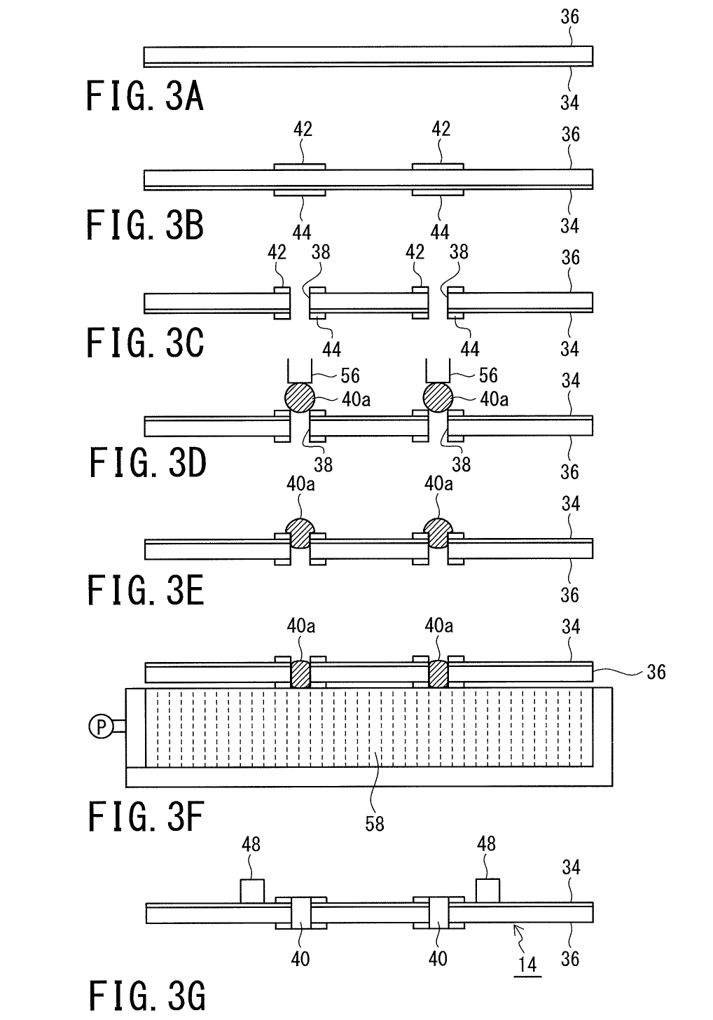

The first film substrate 14 may be produced by the method described below. FIGS. 3A-3G show a method to produce the first film substrate 14. It should be noted that the method described in FIGS. 3A-3G merely show an example of the method, and the method is not limited thereto.

As shown in FIG. 3A, the insulating sealing membrane 34 is first formed on the film 36. Then the conductive patterns are formed on the surfaces of the film 36 and the membrane 34, respectively. Next, as shown in FIG. 3B, the external terminals 42 and internal terminals 44 are formed, for example, by the screen printing method on the surface of the film 36 in the positions in which the open holes 38 are intended to be formed; the external terminals 42 are formed on the surface of the film 36 while the internal terminals 44 are formed on the surface of the membrane 34. Next, as shown in FIG. 3C, the open holes 38 are formed. Next, as shown in FIGS. 3D and 3E, the conductive paste 40a is dropped on the open holes 38, for example, with dispensers 56. If the conductive paste 40a dropped is then dried, the viscosity of the conductive paste is increased.

Next, the conductive paste 40a is drawn by suction from openings of the holes 38 opposite to the openings on which the paste 40a was dropped (i.e., from openings on the surface of the film 36) with the use, for example, of a sintered metal plate 58, and the paste 40a thus penetrates into the open holes 38. Consequently, the open holes 38 are filled and closed with the conductive paste 40a. Simultaneously, the external terminals 42 and the internal terminals 44 are connected to each other by the conductive paste 40a through the open holes 38. Then, the conductive paste 40a is cured or sintered, for example, by heating, and the open holes 38 are thus closed with the conductive material 40. Simultaneously, the external terminals 42 (and the conductive pattern on the film 36) and the internal terminals 44 (and the conductive pattern on the insulating sealing membrane 34) are electrically connected to each other by the conductive material 40. Lastly, as shown in FIG. 3G, the antislip members 48 are formed in predetermined positions on the surface of the insulating sealing membrane 34, for example, by the screen printing method. Thus, the first film substrate 14 is obtained.

As described above, the conductive paste 40a penetrates into the open holes 38 in the first film substrate 14. Being a liquid, the conductive paste 40a effectively penetrates into the open holes 38. Thus, the open holes 38 are easily filled with the conductive paste 40a and densely closed with the paste 40a. Further, though cracks are easily formed in the insulating sealing membrane 34 around the open holes 38 by a stress applied to the membrane 34 upon formation of the holes 38, the liquid paste 40a penetrates into and closes the cracks formed and suppresses deterioration of the sealing property of the first film substrate 14 brought by the cracks. Thus, the open holes 38 are closed so hermetically that the conductive patterns formed on the surfaces of the film 36 and the insulating sealing membrane 34 of the first film substrate 14 are connected to each other while keeping the high sealing property of the film substrate 14.

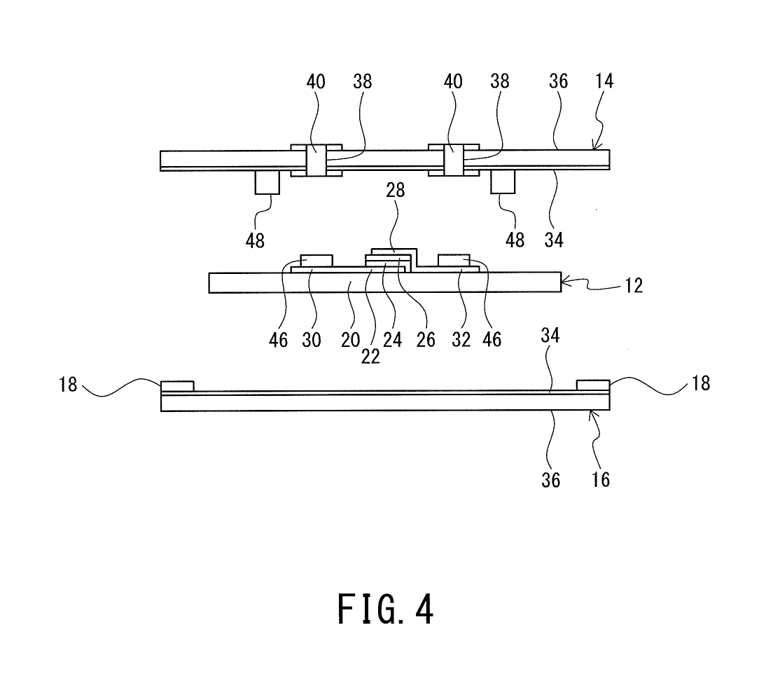

The organic semiconductor device 10 is produced with the use of the first film substrate 14 thus formed, the laminate 12, and the second film substrate 16. FIG. 4 shows a method for producing the organic semiconductor device 10.

As shown in FIG. 4, the laminate 12 is first placed between the first film substrate 14 and the second film substrate 16. Then, the first and second film substrates 14, 16 are joined to each other under pressure via the sealant 18. Upon the joining, a space around the laminate 12 is evacuated so that the content of a gas (or moisture) that is enclosed in the space together with the laminate 12 is decreased. A vacuum oven may be used for the evacuation. While evacuated, the laminate 12 is sealed with the first and second film substrates 14, 16 joined to each other. Simultaneously with the sealing, the conductive material 40, which works as connection lands of the conductive pattern formed on the surface of the insulating sealing membrane 34 of the first film substrate 14, and the anode and cathode contained in the laminate 12 are connected to each other via the conductive adhesive layers 46, with keeping the conductive material 40 and the electrodes aligned with each other.

Since the sealing members 14, 16 that seal the laminate 12 are film materials, the step of sealing under evacuation cause a slip between the films 36 of the film substrates 14, 16 and the laminate 12 if the device 10 does not contain the antislip members 48. In the method described above, connections between the connect ion lands of the conductive pattern and the anode and cathode are formed simultaneously with the sealing of the laminate 12. Thus, the slip between the first film substrates 14, 16 containing the films 36 and the laminate 12 leads to a displacement between the connection positions of the connection lands and the electrodes because the connection lands have very small areas. If the positions of the substrates 14, 16 containing the films 36 are fixed with the use of a positioning device such as a positioning pin before the evacuation in order to suppress the positional displacement, a slipping force may create undulation or distortion in the films 36 upon the evacuation because the films 36 are not rigid bodies. The undulation or distortion may lead to warping of the films 36 after the sealing. The warping makes the connections between the connection lands and the anode and cathode bad.

Meanwhile, in the organic semiconductor device 10 according to the preferred embodiment of the resent invention, the antislip members 48 are placed between the laminate 12 and the first film substrate 14 upon the sealing of the laminate 12. The antislip members 48 suppress the slipping between the laminate 12 and the first film substrate 14 and thus suppress the positional displacement between them, upon the sealing of the laminate 12. Thus, the alignment between the connection lands and the anode and cathode are maintained, and the organic semiconductor device 10 has excellent connection precision between the connection lands and the anode and cathode.

In the organic semiconductor device 10 according to the preferred embodiment of the present invention, the anode and cathode in the laminate 12 are connected to the external driving circuit through the open holes 38 in the first film substrate 14 that seals the laminate 12 containing the organic semiconductor layer 26, but not through a gap between the substrates joined to each other as in the conventional device. Thus, the laminate 12 in the device 10 is highly sealed.

Further, when the conductive adhesive layers 46 are made of the anisotropic conductive paste or film, a part of the paste or film flows into the open holes 38 upon the connection of the electrodes, and the voids generated in the open holes 38 upon curing or sintering of the conductive paste 40a are filled with the anisotropic conductive paste or film. Thus, the sealing of the laminate 12 is ensured further.

In case of the example shown in FIG. 3, the antislip members 48 are formed on the insulating sealing membrane 34 of the first film substrate 14. The antislip members 48 and the open holes 38 are aligned on a straight line in a longitudinal direction of the film substrate. The antislip members 48 are placed outside the open holes 38 on the line. However, the arrangement or number of the antislip members 48 is not limited thereto.

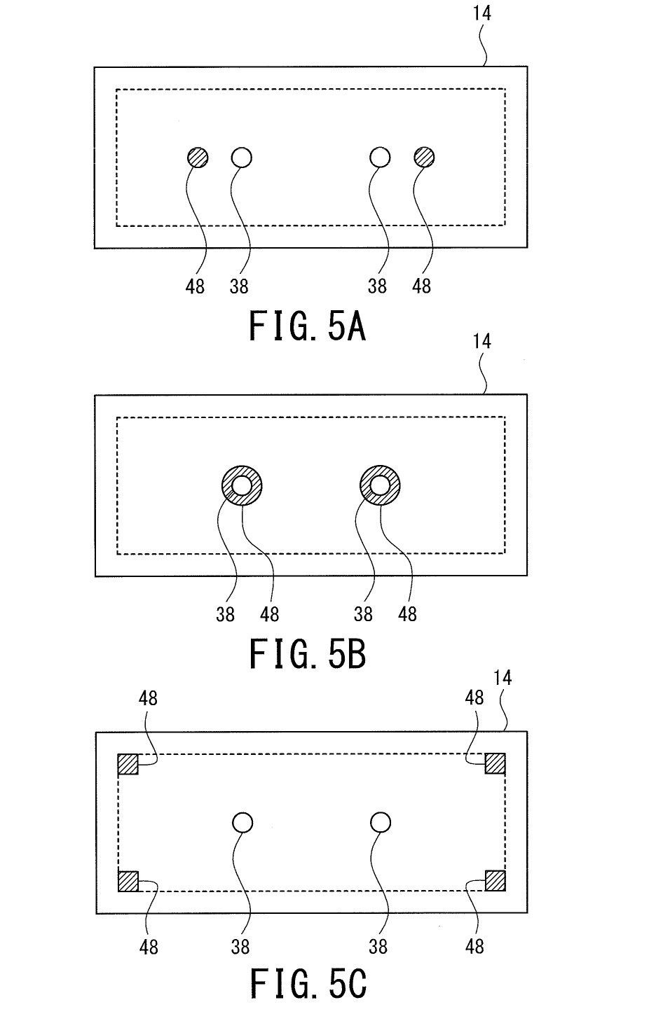

For example, the antislip members 48 may be formed in other positions on the insulating sealing membrane 34 of the first film substrate 14, or in any positions on the surface of the laminate 12 or on the surface of the insulating sealing membrane 34 of the second film substrate 16. FIGS. 5A-5C show variations of the arrangement of the antislip members 48. FIG. 5A shows the arrangement of the antislip members 48 of the first film substrate 14 as shown in FIGS. 3A-3G. The areas inside dashed lines in FIGS. 5A-5C correspond to areas sealed with the sealant 18.

In a variation shown in FIG. 5B, antislip members 48 are formed around peripheries of the open holes 38 on the surface of the insulating sealing membrane 34 of the first film substrate 14. In another variation shown in FIG. 5C, antislip members 48 are formed in four corners on the surface of the insulating sealing membrane 34 of the first film substrate 14.

In the variation shown in FIG. 5B, the antislip members 48 are formed on the surface of the insulating sealing membrane 34 of the first film substrate 14 before the open holes 38 are formed (i.e., before the internal terminals 44 are formed in the step shown in FIG. 3B, in the case of the method shown in FIGS. 3A-3G). Specifically, the antislip members 48 are formed on the surface of the insulating sealing membrane 34 of the first film substrate 14 in positions in which the open holes 38 are intended to be formed, having larger areas than the open holes 38 intended to be formed. Thus, the antislip members 48 relax (or absorb) stresses that are applied around the peripheries of the open holes 38 upon the formation of the open holes 38, and suppresses formation of cracks in the insulating sealing membrane 34 upon formation of the open holes 38 and resultant deterioration of the sealing property of the membrane 34.

It is preferable that two or more antislip members 48, rather than only one, are formed in order to suppress the slipping effectively. Further, it is preferable that the two or more antislip members 48 are arranged symmetrically about the longitudinal or width direction to suppress the slipping with a good balance.

The foregoing description of the preferred embodiments of the present invention has been presented for purposes of illustration and description; however, it is not intended to be exhaustive or to limit the present invention to the precise form disclosed, and modifications and variations are possible as long as they do not deviate from the principles of the present invention.

Though, in the preferred embodiment of the present invention described above, the sealing members 14, 16 are joined to each other via the sealant 18, the sealing members 14, 16 may be joined to each other without the sealant 18, for example, by fusion. Though, in the preferred embodiment of the present invention described above, the connection lands of the conductive pattern formed on the surface of the insulating sealing membrane 34 are provided by the conductive material 40 deposited in the open holes 38 in the first film substrate 14, the connection lands may have any configuration; the connection lands may be formed in other positions in the conductive pattern. Further, the first and second film substrates 14, 16 may have organic protection layers that suppress formation of cracks by bending of the film substrates 14, 16 on the surfaces of the insulating sealing membrane 34 (and between the insulating sealing membrane 34 and the antislip members 48 in the case of the first film substrate 14). The organic protection layers have thicknesses of several tens of nanometer to suppress formation of the cracks by bending sufficiently.

The conductive patterns formed on the surfaces of the film 36 and the insulating sealing membrane 34 of the first film substrate 14 may be connected to each other by a conductive metal-plated layer covering inner circumferential surfaces of the open holes 38 prior to filling of the open holes with the conductive material 40. In such a case, the open holes 38 are so-called “through-holes”.

Though, in the preferred embodiment of the present invention described above, the conductive patterns are formed on the surfaces of both the film 36 and the insulating sealing membrane 34 of the first film substrate 14, it is not necessary that the conductive patterns are formed on the both surfaces. If the conductive patterns are not formed on the both surfaces, the electrodes in the laminate 12 are connected outside the device 10 through the open holes 38 by the conductive material 40.

1. An organic semiconductor device comprising:
a first film substrate comprising a film and an insulating sealing membrane formed on a surface of the film;
a second film substrate comprising a transparent film and an insulating sealing membrane formed on a surface of the transparent film; and
a laminate comprising a transparent substrate, an organic semiconductor layer comprising an organic semiconductor material, an anode layer, and a cathode layer, the laminate enclosed and sealed with the first and second film substrates,
wherein the first film substrate comprises an open hole extending through the thickness of the first film substrate;
the device comprises, between the laminate and at least one of the first and second film substrates, an antislip member that suppresses slipping between the laminate and the at least one of the first and second film substrates that occurs upon sealing of the laminate, and the open hole and an electrode contained in the laminate are kept aligned by the suppression of the slipping; and
the electrode contained in the laminate is connected outside the device through the open hole by a conductive material.

2. The organic semiconductor device according to claim 1, wherein the antislip member is formed between the laminate and the first film substrate around a periphery of the open hole.

3. The organic semiconductor device according to claim 2, wherein the conductive material is a cured or sintered product of a conductive paste deposited in the open hole in the first film substrate, and the open hole is closed with the cured or sintered product.

4. The organic semiconductor device according to claim 3, wherein the cured or sintered product of the conductive paste is electrically connected to the electrode contained in the laminate via an anisotropic conductive paste or film, and a part of the anisotropic conductive paste or film is in the open hole closed with the cured or sintered product.

5. The organic semiconductor device according to claim 4, wherein the conductive paste is a paste-form composition that comprises a conductive filler comprising a metallic nanofiller.

6. The organic semiconductor device according to claim 5, wherein the first and second film substrates are joined to each other at peripheral portions of the film substrates with a sealant, and the laminate is enclosed and sealed hermetically with the first and second substrates.

7. The organic semiconductor device according claim 6, wherein the first film substrate comprises conductive patterns on surfaces of the film and the insulating sealing membrane, and the conductive patterns are electrically connected to each other through the open hole by the conductive material.

8. A method for producing an organic semiconductor device, the device comprising:
a first film substrate comprising a film and an insulating sealing membrane formed on a surface of the film;
a second film substrate comprising a transparent film and an insulating sealing membrane formed on a surface of the transparent film; and
a laminate comprising a transparent substrate, an organic semiconductor layer comprising an organic semiconductor material, an anode layer, and a cathode layer, the laminate enclosed and sealed with the first and second film substrates,
wherein the method comprises:
forming an open hole extending through the thickness of the first film substrate through which an electrode contained in the laminate is to be connected outside the device;
filling the open hole with a conductive material;
enclosing the laminate between the first and second film substrates;
placing, between the laminate and at least one of the first and second film substrates, an antislip member that suppresses slipping between the laminate and the at least one of the first and second film substrates that occurs upon sealing the laminate; and
sealing the laminate and connecting the electrode contained in the laminate outside the device through the open hole via the conductive material, by joining the first and second film substrates to each other under evacuation with keeping the open hole and the electrode contained in the laminate aligned.

9. The method according to claim 8, wherein before the open hole is formed in the first film substrate, the antislip member is formed on the surface of the insulating sealing membrane of the first film substrate in a position in which the open hole is to be formed, having a larger area than the open hole to be formed.

10. The method according to claim 9, wherein the open hole in the first film substrate is filled with the conductive material by depositing of a conductive paste in the open hole and subsequent curing or sintering of the conductive paste.

11. The method according to claim 10, wherein a cured or sintered product of the conductive paste and the electrode contained in the laminate are electrically connected to each other via an anisotropic conductive paste or film, and a part of the anisotropic conductive paste or film is flowed into the open hole closed with the cured or sintered product.

12. The method according to claim 8, wherein the open hole in the first film substrate is filled with the conductive material by depositing of a conductive paste in the open hole and subsequent curing or sintering of the conductive paste.

13. The organic semiconductor device according to claim 3, wherein the conductive paste is a paste-form composition that comprises a conductive filler comprising a metallic nanofiller.

14. The organic semiconductor device according to claim 1, wherein the first film substrate comprises conductive patterns on surfaces of the film and the insulating sealing membrane, and the conductive patterns are electrically connected to each other through the open hole by the conductive material.

15. The organic semiconductor device according to claim 1, wherein the first and second film substrates are joined to each other at peripheral portions of the film substrates with a sealant, and the laminate is enclosed and sealed hermetically with the first and second substrates.

16. The organic semiconductor device according to claim 1, wherein the conductive material is a cured or sintered product of a conductive paste deposited in the open hole in the first film substrate, and the open hole is closed with the cured or sintered product.

17. The organic semiconductor device according to claim 16, wherein the conductive paste is a paste-form composition that comprises a conductive filler comprising a metallic nanofiller.

18. The organic semiconductor device according to claim 16, wherein the cured or sintered product of the conductive paste is electrically connected to the electrode contained in the laminate via an anisotropic conductive paste or film, and a part of the anisotropic conductive paste or film is in the open hole closed with the cured or sintered product.
